(19) United States
(12) Patent Application Publication
(10) Pub. No.: US 2007/0052082 A1
(43) Pub. Date: Mar. 8, 2007

(54) MULTI-CHIP PACKAGE STRUCTURE

(76) Inventors: Cheng-Yin Lee, Tainan City (TW); Chih-Ming Chung, Kaohsiung County (TW); Wen-Pin Huang, Tainan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/306,818

(22) Filed: Jan. 12, 2006

(30) Foreign Application Priority Data
Sep. 2, 2005 (TW) 94130054

(51) Int. Cl. H01L 23/02

(52) U.S. Cl. 257/686

(57) ABSTRACT

A multi-chip package structure including a carrier, a first chip having an active surface and a rear surface, multiple bumps, a second chip, multiple first bonding wires, a package unit disposed above the first chip, a spacer disposed between the package unit and the first chip, multiple second bonding wires, and an encapsulant is provided. The bumps are disposed between the active surface and the carrier to electrically connect the first chip and the carrier. The second chip is disposed on the rear surface of the first chip. The first bonding wires electrically connect the second chip and the carrier. The second bonding wires electrically connect the package unit and the carrier. The encapsulant is disposed on the carrier to encapsulate the first chip, the second chip, at least a portion of the package unit, the bumps, the spacer, the first bonding wires and the second bonding wires.

### CROSS-REFERENCE TO RELATED APPLICATION

This application claims the priority benefit of Taiwan application serial no. 94130054, filed on Sep. 2, 2005. All disclosure of the Taiwan application is incorporated herein by reference.

### BACKGROUND OF THE INVENTION

1. Field of the Invention

The present invention relates to a chip package structure. More particularly, the present invention relates to a multi-chip package structure.

2. Description of the Related Art

In the semiconductor industry, the production of chip package units is mainly divided into two major stages, the chip fabricating stage and the chip packaging stage. In the chip fabricating stage, chips with specified functions are formed by wafers fabrication, circuits design, circuit patterns fabrication and wafers cutting process. In the chip packaging stage, the chip is electrically connected to a carrier and then encapsulated by determined encapsulant to produce a chip package unit. The purpose of packaging the chip is to protect the chip against the effects produced by moisture and heat and provide a medium for connecting the chip to an external circuit. The external circuit may be a printed circuit board (PCB) or other packaging substrate, for example.

In general, most electronic devices such as memories or detectors are fabricated using a multiple of chips having identical or different functions. These packages having a plurality of chips are mostly stacked chip package structures or multi-chip package structures in other configurations.

FIG. 1 is schematic cross-sectional views of a convention multi-chip package structure according to the U.S. Pat. No. 6,838,761. As shown in FIG. 1, the conventional multi-chip package structure 10 comprises a first package unit 100, a second package unit 200, a plurality of bonding wires 218 and an encapsulant 207. The second package unit 200 is disposed above the first package unit 100 and the bonding wires 218 electrically connect the second package unit 200 and the first package unit 100. The encapsulant 207 is disposed over the first package unit 100 to encapsulate the second package unit 200 and the bonding wires 218.

More specifically, the first package unit 100 is a conventional ball grid array (BGA) package. In addition, the first package unit 100 includes a circuit substrate 112, a chip 114, a plurality of bonding wires 116, an encapsulant 117 and a plurality of solder balls 118. The circuit substrate 112 has a plurality of metallic layers 121, 123 and a plurality of conductive vias 122. The metallic layers 121 and 123 are electrically connected to each other through the conductive vias 122. Furthermore, the chip 114 is attached to the circuit substrate 112 through an adhesive layer 113 and the bonding wires 116 electrically connect the chip 114 and the circuit substrate 112. The encapsulant 117 is disposed over the circuit substrate 112 to encapsulate the chip 114 and the bonding wires 116. The solder balls 118 are disposed on the metallic layer 123 of the circuit substrate 112. Moreover, the solder balls 118 are electrically connected to the chip 114 through the circuit substrate 112 and the bonding wires 116.

The second package unit 200 is a conventional land grid array (LGA) package. The second package unit 200 includes a circuit substrate 212, a chip 214, a plurality of bonding wires 216 and an encapsulant 217. The circuit substrate 210 has a plurality of metallic layers 221, 223 and a plurality of conductive vias 222. The metallic layers 221 and 223 are electrically connected each other through the conductive vias 222. The chip 214 is attached to the circuit substrate 212 through an adhesive layer 213. The bonding wires 216 electrically connect the chip 214 and the circuit substrate 212. The encapsulant 217 is disposed over the circuit substrate 212 to encapsulate the chip 214 and the bonding wires 216.

Both the first package unit 100 and the second package unit 200 use a definite number of bonding wires to form the required electrical connections. However, forming these bonding wires is going to take some time.

### SUMMARY OF THE INVENTION

Accordingly, the present invention is directed to provide a multi-chip package structure that can reduce the number of bonding wires used for electrical connections.

As embodied and broadly described herein, the invention provides a multi-chip package structure. The multi-chip package structure comprises a first carrier, a first chip, a plurality of first bumps, a second chip, a plurality of first bonding wires, a package unit, a spacer, a plurality of second bonding wires and an encapsulant. The first chip has an active surface and a rear surface. The first bumps are disposed between the active surface of the first chip and the first carrier. The first chip is electrically connected to the first carrier through the first bumps. The second chip is disposed on the rear surface of the first chip. The first bonding wires electrically connect the second chip with the first carrier. The package unit is disposed above the first chip and the spacer is disposed between the package unit and the first chip. The second bonding wires electrically connect the package unit with the first carrier. The first encapsulant is disposed over the first carrier for encapsulating the first chip, the second chip, at least a portion of the package unit, the first bumps, the spacer, the first bonding wires and the second bonding wires.

According to one embodiment of the present invention, the package unit comprises a second carrier, a third chip, a plurality of third bonding wires and a second encapsulant. The third chip is disposed on the second carrier. The third bonding wires electrically connect the second carrier with the third chip. The second encapsulant is disposed on the second carrier to encapsulate the third chip and the third bonding wires.

According to one embodiment of the present invention, the package unit comprises a second carrier, a third chip, a plurality of second bumps and a second encapsulant. The third chip is disposed on the second carrier. The second bumps are disposed between the third chip and the second carrier. The third chip is electrically connected to the second carrier through the second bumps. The second encapsulant is disposed on the second carrier to encapsulate the third chip and the second bumps.

According to one embodiment of the present invention, a portion of the package unit is exposed by the first encapsulant.

According to one embodiment of the present invention, the spacer may be an insulating film or a dummy chip.

According to one embodiment of the present invention, the multi-chip package structure further includes a third encapsulant for encapsulating the second chip, the first bonding wires, a portion of the first chip and a portion of the first carrier.

According to one embodiment of the present invention, the first carrier has a first surface and a second surface. Furthermore, the first chip, the second chip and the package unit are disposed on the first surface of the first carrier. The multi-chip package structure further includes a plurality of solder balls disposed on the second surface of the first carrier. The solder balls are electrically connected to the first chip, the second chip and the package unit through the first carrier.

Accordingly, the present invention deploys the flip-chip bonding technique and the wire-bonding technique at the same time to form a multi-chip package structure. Therefore, fewer bonding wires are used in the present invention.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is schematic cross-sectional views of a convention multi-chip package structure according to the U.S. Pat. No. 6,838,761.

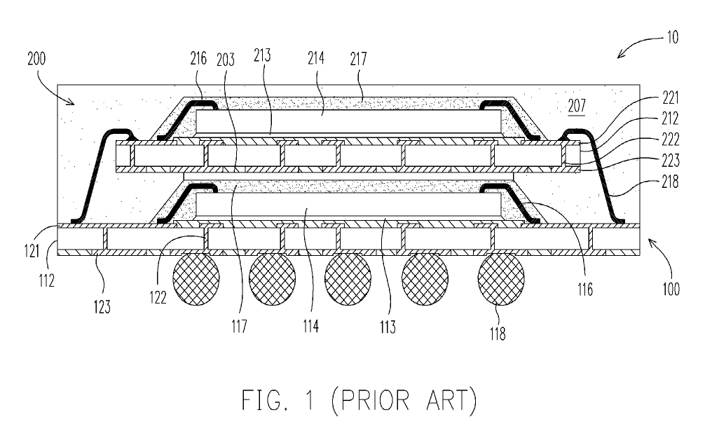

FIG. 2 is a schematic cross-sectional view of a multi-chip package structure according to the first embodiment of the present invention.

FIG. 3 is a schematic cross-sectional view of a multi-chip package structure according to the second embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

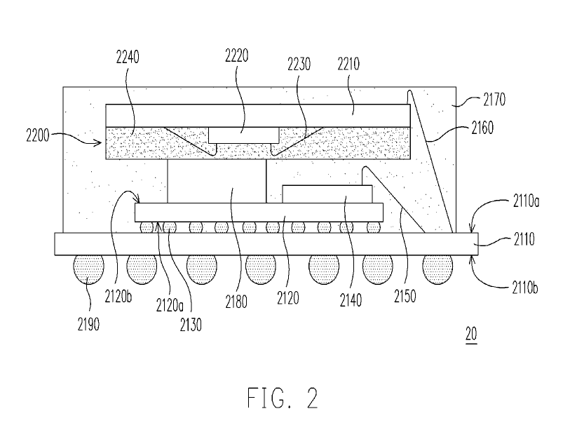

FIG. 2 is a schematic cross-sectional view of a multi-chip package structure according to the first embodiment of the present invention. As shown in FIG. 2, the multi-chip package structure 20 comprises a first carrier 2110, a first chip 2120, a plurality of first bumps 2130, a second chip 2140, a plurality of first bonding wires 21 50, a package unit 2200, a plurality of second bonding wires 2160 and a first encapsulant 2170. The first carrier 2110 has a first surface 2110a and a second surface 2110b. The first chip 2120, the second chip 2140, the package unit 2200 are disposed on the first surface 2110a of the first carrier 2110. In the present embodiment, the first carrier 2110 is a circuit substrate. However, the first carrier 2110 can also be a lead frame or some other forms of carriers.

The first chip 2120 has an active surface 2120a and a rear surface 2120b. The first bumps 2130 are disposed between the active surface 2120a of the first chip 2120 and the first carrier 2110. The first chip 2120 is electrically connected to the first carrier 2110 through the first bumps 2130. In other words, the first chip 2120 is electrically connected to the first carrier 2110 by flip-chip bonding process. The second chip 2140 is disposed on the rear surface 2120b of the first chip 2120. The first bonding wires 2150 electrically connect the second chip 2140 with the first carrier 2110.

The package unit 2200 is disposed above the first chip 2120. The second bonding wires 2160 electrically connect the package unit 2200 with the first carrier 2110. The first encapsulant 2170 is disposed over the first carrier 2110 for encapsulating the first chip 2120, the second chip 2140, at least a portion of the package unit 2200, the first bumps 2130, the first bonding wires 2150 and the second bonding wires 2160. In the present embodiment, the first encapsulant 2170 may expose a portion of the package unit 2200. In an alternately embodiment, the first encapsulant 2170 can cover the package unit 2200 entirely. Furthermore, an underfill layer may also be disposed between the first chip 2120 such that the first carrier 2110 with the first encapsulant 2170 may further encapsulate the underfill layer.

The package unit 220 can be a wire-bonded package, a flip-chip package or other types of package. In the present embodiment, the package unit 2200 is a wire-bonded package. The package unit 2200 comprises a second carrier 2210, a third chip 2220, a plurality of third bonding wires 2230 and a second encapsulant 2240. The second carrier 2210 can be a circuit substrate, a lead frame or other type of carrier. The third chip 2200 is disposed on the second carrier 2210. The third bonding wires electrically connect the second carrier 2210 with the third chip 2220. The second encapsulant 2240 is also disposed on the second carrier 2210 to encapsulate the third chip 2220 and the third bonding wires 2230.

It should be noted that the multi-chip package structure may further include a spacer 2180 to prevent the package unit 2200 from compressing the first bonding wires 2150. The spacer 2180 is disposed between the package unit 2200 and the first chip 2120. The spacer 2180 can be a thick insulating film or a dummy chip, for example. The thick insulating film can be fabricated using epoxy resin or some other insulating material. In addition, an adhesive layer may be also formed between the spacer 2180 and the first chip 2120 as well as between the spacer 2180 and the package unit 2200 such that the package unit 2200 can be fixed firmly.

To provides a electrical connection between the first carrier 2110 and the external (for example, a printed circuit board), the multi-chip package structure 20 may further includes a plurality of solder balls 2190 disposed on the second surface 2110b of the first carrier 2110. The solder balls 2190 are electrically connected to the first chip 2120, the second chip 2140 and the package unit 2200 through the first carrier 2110. However, the solder balls 2190 can be changed to pins or some other forms of electrical terminals. When compared with other conventional techniques, the present invention can accommodate more chips with fewer bonding wires. In other words, the present invention can reduce the time required to form all the bonding wires and increase the number of electrical terminals.

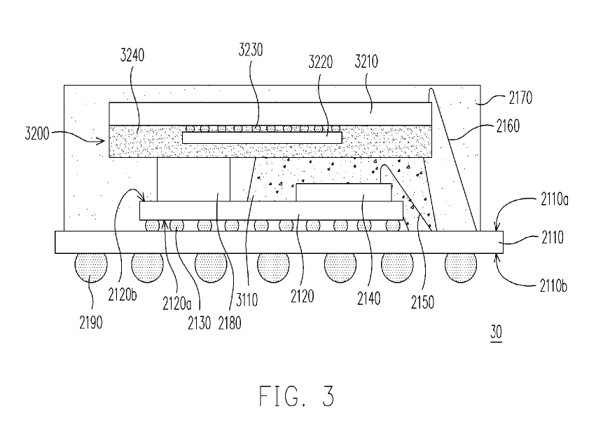

FIG. 3 is a schematic cross-sectional view of a multi-chip package structure according to the second embodiment of the present invention. As shown in FIG. 3, the present embodiment is similar to the foregoing embodiment. One major difference is that the multi-chip package structure 30 in the present embodiment further includes a third encapsulant 3110 that encapsulates the second chip 2140, the first bonding wires 2150, a portion of the first chip 2120 and a portion of the first carrier 2110. In other words, the third encapsulant 3110 is provided to protect the first bonding wires 2150. In addition, the package unit 2200 in the aforementioned embodiment is a wire-bonded package while the package unit 3200 in the present embodiment is a flip-chip bonded package.

More specifically, the package unit 3200 includes a second carrier 3210, a third chip 3220, a plurality of second bumps 3230 and a second encapsulant 3240. The second carrier 3210 can be a circuit substrate or a lead frame. The third chip 3220 is disposed on the second carrier 3210. The second bumps 3230 are disposed between the third chip 3220 and the second carrier 3210. The third chip 3220 is electrically connected to the second carrier 3210 through the second bumps 3230. Furthermore, the second encapsulant 3240 is disposed on the second carrier 3210 to encapsulate the third chip 3220 and the second bumps 3230.

However, an underfill layer can be further disposed between the second carrier 3210 and the third chip 3220 to encapsulate the second bumps 3230. Furthermore, the underfill layer and the second encapsulant 3240 can be disposed together or separately disposed. Moreover, an adhesive layer may also be disposed between the second encapsulant 3240 and the third encapsulant 3110 such that the package unit 3200 can be fixed firmly. To disposition the package unit 3220 more firmly above the first carrier 2110, a plurality of second chips 2140 and a third encapsulant 3110 may be disposed on the first chip 2120. In the present embodiment, the first encapsulant 2170 completely encapsulates the package unit 3200. However, a portion of the package unit 3200 may also be exposed by the first encapsulant 2170.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A multi-chip package structure, comprising:
a first carrier;
a first chip having an active surface and a rear surface;
a plurality of first bumps disposed between the active surface of the first chip and the first carrier, wherein the first chip is electrically connected to the first carrier through the first bumps;
a second chip disposed on the rear surface of the first chip;
a plurality of first bonding wires connecting the second chip and the first carrier electrically;
a package unit disposed above the first chip;
a spacer disposed between the package unit and the first chip;
a plurality of second bonding wires connecting the package unit and the first carrier electrically; and
a first encapsulant disposed over the first carrier to encapsulate the first chip, the second chip, at least a portion of the package unit, the first bumps, the spacer, the first bonding wires and the second bonding wires.

2. The multi-chip package structure of claim 1, wherein the package unit comprises:
a second carrier;
a third chip disposed over the second carrier;
a plurality of third bonding wires connecting the second carrier and the third chip electrically; and
a second encapsulant disposed over the second carrier to encapsulate the third chip and the third bonding wires.

3. The multi-chip package structure of claim 1, wherein the package unit comprises:
a second carrier;
a third chip disposed over the second carrier;
a plurality of second bumps disposed between the third chip and the second carrier, wherein the third chip is electrically connected to the second carrier through the second bumps; and
a second encapsulant disposed over the second carrier to encapsulate the third chip and the second bumps.

4. The multi-chip package structure of claim 1, wherein a portion of the package unit is exposed by the first encapsulant.

5. The multi-chip package structure of claim 1, wherein the spacer comprises an insulating film or a dummy chip.

6. The multi-chip package structure of claim 1, further comprising a third encapsulant for encapsulating the second chip, the first bonding wires, a portion of the first chip, and a portion of the first carrier.

7. The multi-chip package structure of claim 1, wherein the first carrier has a first surface and a second surface, such that the first chip, the second chip, and the package unit are disposed on the first surface of the first carrier.

8. The multi-chip package structure of claim 7, further comprising a plurality of solder balls disposed on the second surface of the first carrier, such that the solder balls are electrically connected to the first chip, the second chip and the package unit through the first carrier.
